(19) United States
(12) Patent Application Publication
(10) Pub. No.: US 2024/0101446 A1
(43) Pub. Date: Mar. 28, 2024

(54) VAPORIZER AND VAPORIZATION SUPPLY DEVICE

(71) Applicant: FUJIKIN INCORPORATED, Osaka (JP)

(72) Inventors: Ichiro TOKUDA, Osaka-shi (JP); Mizuki NAKAGAWA, Osaka-shi (JP); Keiji HIRAO, Osaka-shi (JP); Yukio MINAMI, Osaka-shi (JP)

(73) Assignee: FUJIKIN INCORPORATED, Osaka (JP)

(21) Appl. No.: 18/264,501

(22) PCT Filed: Feb. 1, 2022
(86) PCT No.: PCT/JP2022/003750

§ 371 Date: Aug. 7, 2023

(30) Foreign Application Priority Data
Mar. 11, 2021 (JP) 2021-038960

(51) Int. Cl. C02F 1/04; F22B 1/28; F22B 37/44; F22D 1/00; H01L 21/67

(52) U.S. Cl. CPC C02F 1/045; F22B 1/28; F22B 37/44; F22D 1/003; H01L 21/67017; C02F 2103/04

(57) ABSTRACT

A vaporizer 10 comprises: a vaporization chamber 12 for storing a liquid; a bottom heater 14B provided in the vaporization chamber 12 which includes a winding portion 141, acting as a heat source, to contact with the liquid stored in the vaporization chamber and an upright portion 142 erected from the winding portion and having an end portion with a heater terminal 143; and a relief valve 16 connected to the vaporization chamber 12. The vaporizer 10 is configured to be able to appropriately vaporize and supply ultrapure water.

### TECHNICAL FIELD

The present invention relates to a vaporizer and a vaporization supply device, in particular, to a vaporizer and a vaporization supply device including the same that is appropriately used for supplying vaporized ultrapure water to an ashing device or the like provided in a semiconductor manufacturing apparatus.

### BACKGROUND ART

In the semiconductor manufacturing field, the ashing device or asher is widely utilized in order to remove a photoresist film formed on a substrate after patterning. In recent years, the development of equipment is also advanced for performing ashing by generating plasma using ultrapure water as a raw material and reacting the plasma with the photoresist film. By performing dry process ashing using ultrapure water in this manner, it is possible to reduce adverse effect on the produced semiconductor device and reduce the impact on environment.

As the ashing device using ultrapure water, one is known to perform ashing using water vapor plasma generated by microwave excitation. The water vapor used as a raw material gas, for example, can be generated by reducing a pressure to vaporize the ultrapure water introduced into a processing chamber.

In addition, in an ashing device of another aspect, ultrapure water may be previously vaporized using a heater or a vaporizer, and introduced into a processing chamber as the raw material gas, whereby water vapor plasma can be generated (for example, Patent Literature 1).

In the system of supplying vaporized ultrapure water by using a vaporizer or the like, it is possible to introduce the ultrapure water gas at a predetermined temperature into the processing chamber at a controlled flow rate, thereby, an advantage of possibly reducing the power required for plasma discharge may be obtained. Further, as described in Patent Literature 2, the ultrapure water gas controlled to an appropriate temperature may be used for removing an organic substance such as a photoresist by being blown directly onto a surface of the substrate.

### PRIOR-ART DOCUMENTS

### Patent Literatures

Patent literature 1: Japanese Laid-Open Patent Publication No. 2001-308070
Patent literature 2: Japanese Laid-Open Patent Publication No. 2002-110611
Patent literature 3: International Publication No. WO2015/083343
Patent literature 4: Japanese Laid-Open Patent Publication No. 2001-99765
Patent literature 5: Japanese Laid-Open Patent Publication No. 2004-63715

### SUMMARY OF INVENTION

### Technical Problem

However, the present inventors have found that, in the case of supplying vaporized ultrapure water using a vaporizer, depending on the configuration of the gas supply system, the gas may not be properly supplied at a desired flow rate over the entire period from the start to the end of the supply.

The present invention has been made in order to solve the above problem, and a main object is to provide a vaporizer and a vaporization supply device comprising the vaporizer that are suitably used in supplying vaporized ultrapure water to an ashing device or the like.

### Solution to Problem

The vaporizer according to an embodiment of the present invention comprises a vaporization chamber for storing a liquid; a bottom heater provided in the vaporization chamber and including a winding portion acting as a heat source arranged so as to contact with the liquid stored in the vaporization chamber and an upright portion erected from the winding portion and having an end portion with a heater terminal; and a relief valve connected to the vaporization chamber.

In one embodiment, the vaporizer further comprises a side heater for heating a side surface of the vaporization chamber from outside of the vaporization chamber.

In one embodiment, the vaporizer further comprises a pre-tank having a heater for preheating a liquid to be delivered to the vaporization chamber.

In one embodiment, the vaporizer further comprises a float sensor for measuring a liquid level of the liquid, wherein the winding portion of the bottom heater is provided at a position that is lower than a lower limit position of the liquid level of the float sensor.

In one embodiment, the vaporizer further comprises a stirring device or a swinging device for promoting the movement of the liquid stored in the vaporization chamber.

In one embodiment, the liquid is ultrapure water and the vaporizer is used for supplying vaporized ultrapure water to an ashing device.

The vaporization supply device according to one embodiment of the present invention comprises any one of the above vaporizer and a pressure type flow rate control device provided downstream of the vaporizer, wherein the pressure type flow rate control device includes a restriction part, a control valve provided upstream of the restriction part; and an upstream pressure sensor for measuring a pressure between the restriction part and the control valve, and the pressure type flow rate control device is configured to control the flow rate of the gas flowing downstream of the restriction part by adjusting an opening degree of the control valve in accordance with an output of the upstream pressure sensor.

### Effect of Invention

By utilizing the vaporizer and the vaporization supply device according to the embodiments of the present invention, it is possible to vaporize ultrapure water and appropriately supply it as a gas at a larger flow rate.

### BRIEF DESCRIPTION OF DRAWINGS

FIG. 1 is a schematic diagram showing an ultrapure water gas supply system comprising the vaporizer and the vaporization supply device according to an embodiment of the present invention.

FIG. 2 is a schematic diagram showing an exemplary configuration of a main tank of the vaporizer shown in FIG. 1.

FIG. 3 is a perspective view showing a bottom heater provided in the main tank.

FIG. 4 is a perspective view showing a more specific design example of the main tank.

FIG. 5 is a perspective view showing a configuration in the vicinity of the flow rate control device connected to the downstream side.

### DESCRIPTION OF EMBODIMENTS

The present applicant has been developing a device for supplying ultrapure water to an ashing device after vaporizing it using a vaporizer. The gas generated by the vaporizer is supplied to the ashing device after the flow rate being controlled by a pressure type flow rate control device provided downstream, for example.

Here, the pressure type flow rate control device includes a restriction part such as an orifice plate or a critical nozzle and is a device for controlling the downstream flow rate by controlling the pressure upstream of the restriction part (hereinafter, sometimes referred to as upstream pressure P1) (e.g., Patent Literature 3). The upstream pressure P1 is measured by using a pressure sensor and is controlled by feedback controlling an opening degree of the control valve provided upstream of the restriction part on the basis of an output of the pressure sensor.

The pressure type flow rate control device is widely utilized, because mass flow rate of various fluids can be controlled with high accuracy by a relatively simple mechanism that is a combination of a control valve and a restriction part. Further, the pressure type flow rate control device has a feature that is excellent in stable flow rate control, even if the pressure upstream of the control valve (hereinafter sometimes referred to as the supplied pressure P0) fluctuates, the flow rate fluctuates as hardly as possible, as long as the upstream pressure P1 is appropriately controlled.

However, in the case where the pressure type flow rate control device is provided downstream, especially when the ultrapure water gas is supplied at a large flow rate (e.g., 10 g/min or more or 8000 sccm or more), a relatively high pressure gas is required to be delivered from the vaporizer, and the pressure inside the vaporization chamber needs to be maintain at, for example, 300 kPa or more. Therefore, in order to vaporize ultrapure water under high pressure, the ultrapure water needs to be heated to a temperature of, for example, 130° C. or higher.

Therefore, in the vaporizer fabricated by the present applicant, the ultrapure water was preheated in a pre-tank before it is delivered to the vaporization chamber provided in the main tank, whereby the ultrapure water having a relatively high temperature was vaporized by a heater in the vaporization chamber.

However, according to the experiments conducted by the present inventors, it is found that in the case of supplying the ultrapure water gas at a larger flow rate, a larger capacity is needed for the vaporization chamber. If heating by the heater is not performed at a higher efficiency than before in the main tank, at the start of the gas supply, a decrease in water temperature due to vaporization of the ultrapure water (latent heat) may occur, and a decrease in gas pressure may also occur. Then, there is a possibility that the flow rate control using the pressure type flow rate control device does not function due to the decrease in the gas pressure.

In addition, in order to cope with the large flow rate, it is conceivable to construct a higher pressure and higher temperature environment by increasing the heating time of the heater before the gas supply. However, it is difficult to set an excessive high pressure because reverse flow occurs when the pressure in the vaporization chamber becomes equal to or higher than the ultrapure water supply pressure (for example, 400 kPa). Even though the water temperature drop during gas consumption can be detected by the temperature sensor, and operation can be controlled so as to return to a predetermined temperature by the heat control of the temperature controller, the temperature may not return immediately if the heating efficiency of the heater is low. This may cause decrease in the gas pressure and malfunction in the pressure type flow rate control device.

In addition to the problems at the start of the gas supply described above, the gas pressure in the vaporization chamber increases because the control valve and the downstream shut-off valve of the pressure type flow rate control device is closed at the time of stopping the gas supply. Then, it is also found that particularly in order to cope with the supply of the large flow rate gas, for the sake of safety, it is required that pressure in the large capacity vaporization chamber does not become excessive high, therefore, it is preferred to provide a function capable of preventing the increase in the gas pressure at the time of stopping supply.

Based on the above findings, while performing heating by the heater in the vaporization chamber of the main tank with higher efficiency, the present inventors have intensively studied the vaporizer and the vaporization supply device with safety measures, and has reached the completion of the present invention. Thereby, for example, it has become possible to stably perform the vaporization and supply of ultrapure water at 10 g/min or higher, particularly at 20 g/min or higher, from the staring time to the stopping time.

Embodiments of the present invention will be described below with reference to the drawings, but the present invention is not limited to the following embodiments.

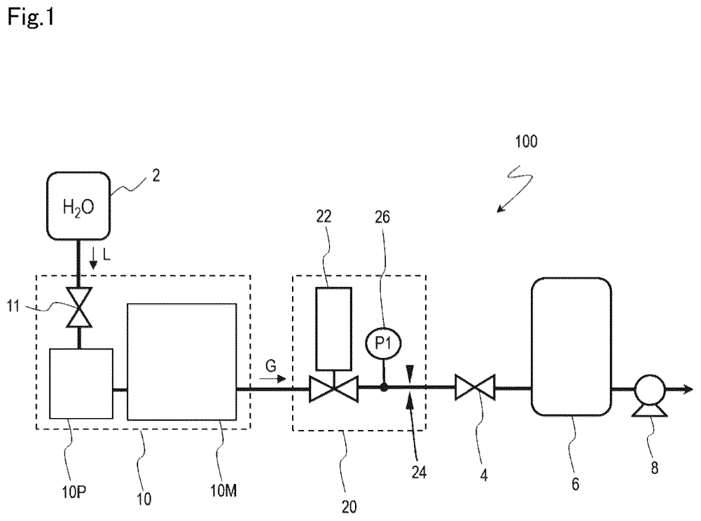

FIG. 1 illustrates an ultrapure water gas supply system having a vaporization supply device 100 according to an embodiment of the present invention. The upstream side of the vaporization supply device 100 is connected to an ultrapure water (H₂O) source 2, and the downstream side is connected to a process chamber 6 via a shut-off valve 4. A vacuum pump 8 is connected to the process chamber 6 and is capable of decreasing pressure inside the chamber and the gas flow path.

The vaporization supply device 100 of the present embodiment comprises a vaporizer 10 and a pressure type flow rate control device 20 connected to the downstream side of the vaporizer 10. The vaporizer 10 receives the ultrapure water pumped from the ultrapure water source 2 in the state of a liquid L, and vaporizes it by heating with a heater. Then, an ultrapure water gas G generated in the vaporizer 10 is flow rate controlled by the pressure type flow rate control device 20 and is supplied to the process chamber 6 at a desired flow rate.

The pressure type flow rate control device 20 comprises a control valve 22, a restriction part 24, and an upstream pressure sensor 26 provided therebetween. By feedback-controlling the control valve 22 based on an output of the upstream pressure sensor 26, the upstream pressure P1 can be maintained at a pressure corresponding to the desired flow rate. As the control valve 22, a piezoelectric element driven valve may be used for example, and as the restriction part 24, an orifice plate with a drilled small hole may be used for example.

The pressure type flow rate control device 20 performs flow rate control by utilizing the principle that, when the critical expansion condition P1/P2≥about 2 (in the case of argon gas) is satisfied, the flow rate Q is determined by the upstream pressure P1 regardless of the downstream pressure P2 which is the pressure downstream of the restriction part 24. When the critical expansion condition is satisfied, the flow rate Q downstream of the restriction part 24 is given by Q=K1·P1 (where K1 is a constant depending on the fluid species and the fluid temperature). The flow rate Q is proportional to the upstream pressure P1. Further, the pressure type flow rate control device 20 may be provided with a downstream pressure sensor (not shown) for measuring the downstream pressure P2. In this case, the flow rate can be calculated even when the critical expansion condition is not satisfied. It is possible to calculate the flow rate Q from Q=K2·P2^{m}(P1−P2)ⁿ (where K2 is a constant depending on the fluid species and fluid temperature, m and n are indexes derived from the actual flow rate).

The pressure type flow rate control device 20 computes the calculated flow rate from time to time, by using the flow rate calculation formula in the critical expansion condition or the non-critical expansion condition Q=K1·P1 or Q=K2·P2^{m} (P1−P2)ⁿ, and feedback controls the control valve 22 so as the flow rate of the gas passing through the restriction part 24 is close to a set flow rate (i.e., so as the difference between the calculated flow rate and the set flow rate approaches 0). Thereby, it is possible to flow the gas at a desired set flow rate downstream of the restriction part 24.

Further, the vaporizer 10 of the present embodiment includes a pre-tank 10P and a main tank 10M downstream thereof. The ultrapure water is supplied to the pre-tank 10P from an ultrapure water source 2 through a liquid feed valve 11, where it is preheated to a predetermined temperature to the extent that it does not vaporize, by using a heater and a temperature sensor (not shown). By providing the pre-tank 10P, vaporization in the main tank 10M can be carried out more easily. Furthermore, the amount of the ultrapure water to be supplied to the pre-tank 10P may be arbitrarily adjusted by controlling the timing of the opening and closing and the opening period of the liquid supply valve 11.

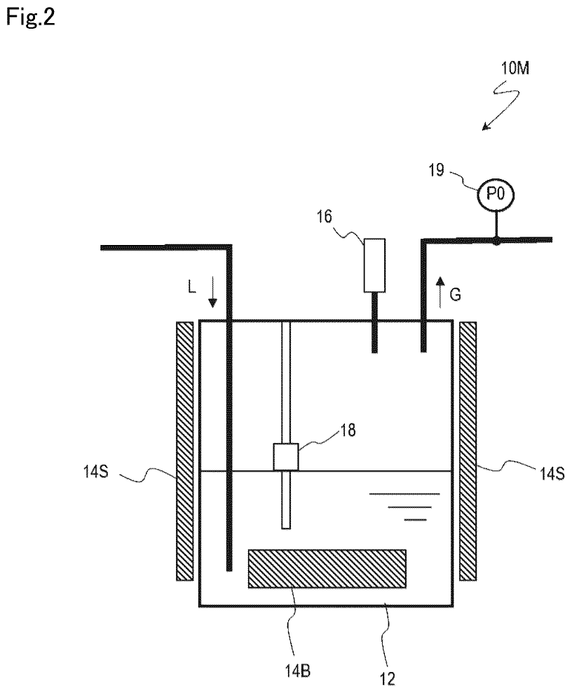

Hereinafter, the detailed configuration of the main tank 10M provided in the vaporizer 10 will be described. As shown in FIG. 2, the main tank 10M includes a vaporization chamber 12 for storing and vaporizing the preheated ultrapure water; a bottom heater 14B provided at the bottom portion of the vaporization chamber 12; and a side heater 14S provided to a side surface of the vaporization chamber 12. The vaporization chamber 12 is formed, for example, by a stainless-steel container having a relatively large volume of 1500 cc to 2000 cc. In the present embodiment, the capacity of the vaporization chamber 12 is set larger than the volume (e.g., 1000 cc to 1500 cc) of the pre-tank 10P.

Further, a relief valve 16 is connected to the vaporization chamber 12. The relief valve 16 is a valve for automatically releasing pressure when an excessive pressure is generated and opens only when the pressure becomes a set pressure or more. Thus, when the gas supply is stopped, the vaporization chamber 12 can be prevented from becoming excessive pressure. The internal pressure of the vaporization chamber 12 may be measured by a supply pressure sensor 19 provided in the gas discharge path, but the supply pressure sensor 19 may not necessarily be provided.

Furthermore, a level sensor 18 capable of measuring a liquid level is provided inside the vaporization chamber 12. In the present embodiment, as the level sensor 18, a float sensor (e.g., 1 float 2 contact point alarm type) is used. A lower limit position is set in the float sensor, and the float sensor is able to output an alarm signal when it detects that the float has dropped below the set lower limit position.

Upon receipt of the alarm signal from the level sensor 18, the vaporizer 10 may open the liquid supply valve 11 and refill the vaporization chamber 12 with ultrapure water through the pre-tank 10P. whereby a certain amount or more of ultrapure water may be always stored in the vaporization chamber 12.

Next, the detailed configuration of the bottom heater 14B and the side heater 14S will be described. The bottom heater 14B and the side heater 14S are used for vaporizing the ultrapure water in the vaporization chamber 12. In the present embodiment, as the side heater 14S, a space heater provided so as to heat the side surface of the vaporization chamber 12 from the outside of the vaporization chamber 12 is used. On the other hand, as the bottom heater 14B, a sheath heater provided inside the vaporization chamber 12 and contacting with the ultrapure water is used. The vaporizer having a heater inside the liquid storage tank is disclosed in Patent Literature 4 and Patent Literature 5.

Here, the space heater is a planar heater in a flat plate shape and is configured to heat a metal surface. Further, the sheath heater has a nichrome wire extending in the heater pipe (sheath) filled with an insulating powder such as MgO. The sheath heater is configured so that the nichrome wire generates heat by electrifying it through a terminal.

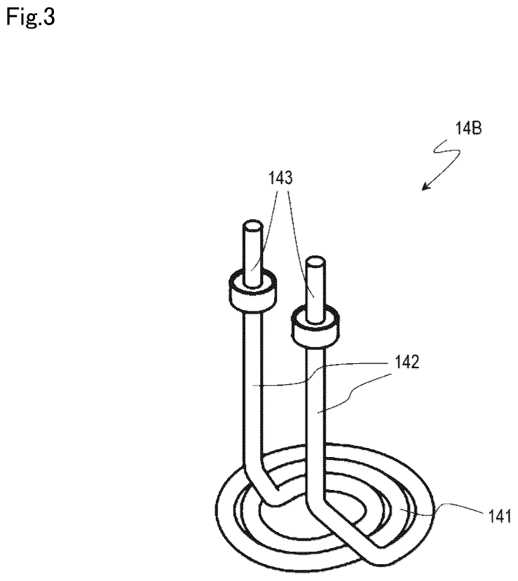

FIG. 3 illustrates a sheath heater used as the bottom heater 14B in the present embodiment. As shown in the drawing, the bottom heater 14B is formed of a single sheath pipe having heater terminals 143 and 143 connected to an external power supply (not shown) on the two ends, with upright portions 142 and 142 formed so as the heater terminals 143 and 143 are adjacent, and the central portion is bended to form a winding portion 141 (i.e. nichrome wire arrangement portion) functioning as the heat source. The winding portion 141 is twice semi-wound in the embodiment shown, but it is needless to say more wounds may be applied. Further, it may have a meandering shape to increase the in-plane contact area. Then, the bottom heater 14B is arranged so that the heater terminals 143 and 143 are protruding from the top surface of the tank to the outside, and the winding portion 141 is located in the vicinity of the bottom of the tank. The heater terminals 143 and 143 may be in a bundle.

By using the bottom heater 14B having such a configuration, it is possible to directly heat the ultrapure water particularly in the lower portion of the vaporization chamber 12 more efficiently. Therefore, even when flowing a large flow rate of ultrapure water gas, it is possible to prevent a decrease in temperature of the ultrapure water in the vaporization chamber, therefore, it is possible to prevent the occurrence of malfunction of the pressure type flow rate control device 20 due to the decrease in gas pressure. Incidentally, the decrease in the temperature of the ultrapure water in the vaporization chamber is measured by a temperature sensor (not shown). The temperature may be maintained by operating the bottom heater 14B and the side heater 14S using a temperature controller.

The bottom heater 14B may have any configuration, as long as the heat source unit (here the winding portion 141 of the sheath heater) is in the vicinity of the bottom of the vaporization chamber 12. Here, the vicinity of the bottom of the vaporization chamber 12 typically means the height position of half or less of the total height of the vaporization chamber 12 in the height direction of the vaporization chamber 12, more specifically, it means the height position of ⅓ or less of the total height. In order to place the heat source unit in such a position, the length of the upright portions 142 of the sheath heater is typically designed to be more than half the length of the total height of the vaporization chamber 12, more specifically, it is set to a length of ⅔ or more of the total height.

Further, the heat source portion of the bottom heater 14B (here the winding portion 141 of the sheath heater) is provided at a position lower than the lower limit position liquid level of the float sensor. Therefore, the heat source portion is always immersed in the liquid by replenishing the ultrapure water, so that the damage of the device by empty firing is also prevented.

Since the space heater constituting the side heater 14S is provided to the outer side of the main tank 10M, it may be installed after tank assembly, but because the bottom heater 14B is disposed inside the vaporization chamber 12, it is required to be assembled inside during tank assembly. The bottom heater 14B, for example, may be fixed by welding the terminal portions into the cover member constituting the upper surface of the vaporization chamber. Thus, by providing only the bottom heater 14B, which is constantly in contact with the ultrapure water, inside the vaporization chamber 12, it is possible to efficiently heat the ultrapure water, while suppressing the complexity of the configuration and assembly process as much as possible.

In the vaporizer 10 described above, it is possible to perform heating more efficiently by the bottom heater 14B, even when using the pressure type flow rate control device 20, ultrapure water gas of a large flow rate can be continuously supplied from the start of the supply at a desired flow rate. Further, since a relief valve 16 is provided, it is possible to prevent the pressure inside the vaporization chamber from becoming excessive at the time of terminating the gas supply, and to prevent damage to the internal float sensor and the valve, thus to ensure safety.

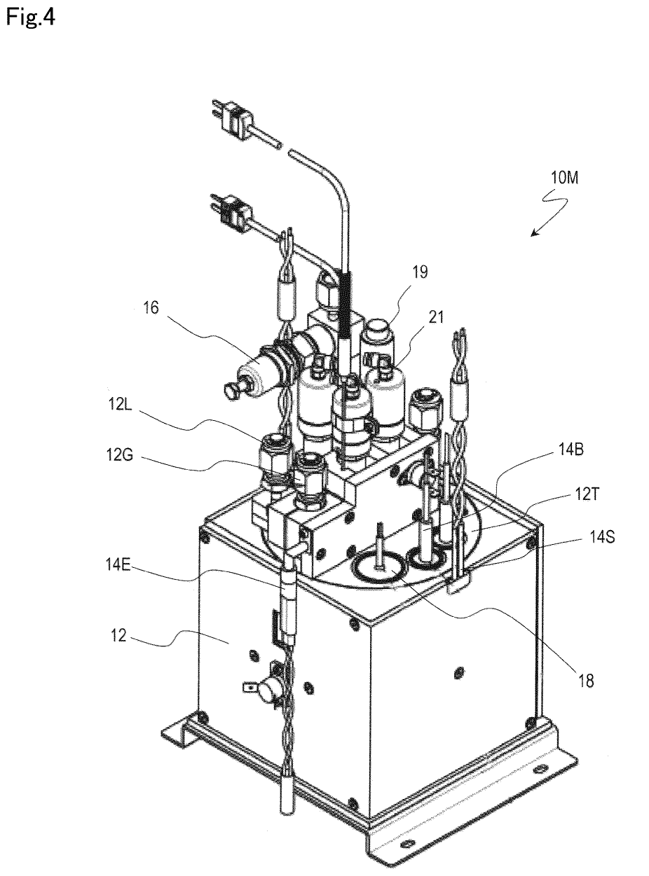

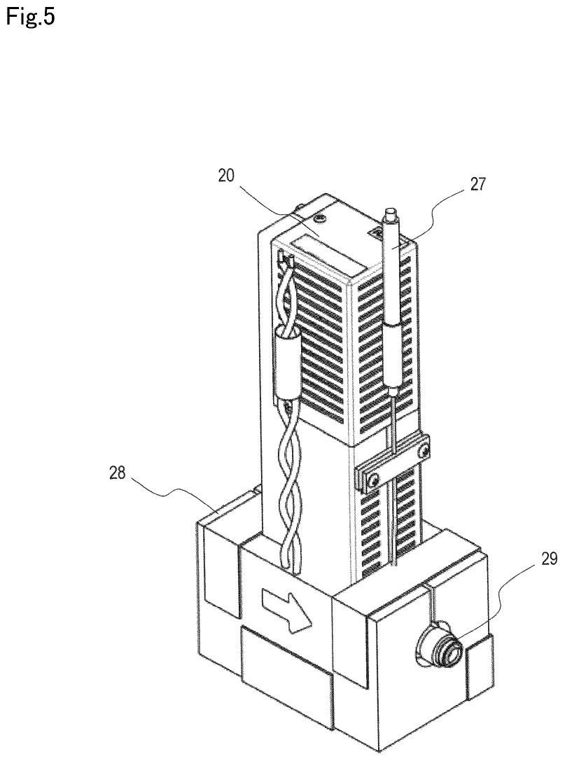

FIG. 4 illustrates a more specific configuration example of the main tank 10M. FIG. 5 illustrates a configuration example of the vicinity of the pressure type flow rate control device 20 connected to the downstream side of the main tank 10M.

As shown in FIG. 4, the main tank 10M is provided with a vaporization chamber 12 having a cubic-like appearance. An ultrapure water inlet 12L connected to the pre-tank 10P and an ultrapure water gas outlet 12G connected to the pressure type flow control device 20 are provided on the upper surface of the vaporization chamber 12.

The space heaters constituting the side heaters 14S are provided on the peripheral four side surfaces so as to surround the vaporization chamber 12. On the other hand, the terminal portions of the bottom heater 14B are fixed by welding to a cover member 12T provided on the upper surface of the vaporization chamber 12, the heating portion of the bottom heater 14B is disposed on the bottom inside the vaporization chamber 12. In the assembly process of the main tank 10M, by fixing the cover member 12T, which has been fixed to the bottom heater 14B, so as to close the upper opening of the vaporization chamber 12, the vaporization chamber 12 is formed as a sealed space while incorporating the bottom heater 14B.

In addition, on the cover member 12T, the above-described relief valve 16, the terminal portions of the level sensor 18, the supply pressure sensor 19 are also fixed. Further, in the present embodiment shown, an air driven valve (AOV) used as the downstream side gas shut-off valve 21 is also fixed, and the cartridge heater constituting the outlet heater 14E is fixed in the vicinity of the ultrapure water gas outlet 12G. This cartridge heater is buried in a metallic member with good thermal conductivity, and is used to prevent reliquefaction of ultrapure water gas by heating the gas flow path leading to the ultrapure water gas outlet 12G.

Furthermore, as shown in FIG. 5, a heat insulation heater 28 such as a jacket heater may also be provided on the pressure type flow rate control device 20 on the downstream side. The temperature of the pressure type flow rate control device 20 is measured by using a temperature sensor 27 (here thermocouple) and is adjusted to a temperature at which reliquefaction of the gas in the vicinity of the pressure type flow rate control device 20 can be prevented (e.g., about 150° C.). Thus, the gas from the gas outlet 29 may be supplied to the process chamber at controlled flow rate while being maintained at a high temperature. Incidentally, a pipe connecting the main tank 10M and the pressure type flow rate control device 20 and a pipe downstream of the pressure type flow rate control device 20 are also preferably maintained at a temperature at which reliquefaction is prevented using a heater or the like. However, since the pipe between the pre-tank 10P and the main tank 10M has a small volume (for example, 5 cc or less), it is sufficient if heat insulation can be secured by being covered with a heat insulating material or the like, it has been confirmed that the temperature drop in the vaporization chamber 12 is not an issue by supplying hot water every 20 to 30 seconds, for example.

As described above, while improving the heating efficiency for vaporization in the main tank 10M, by also heating the gas flow path including the pressure type flow rate control device 20, it is possible to supply high temperature and high pressure ultrapure water gas to the process chamber at a controlled large flow rate.

One aspect of the present invention was described above, but in another aspect, the main tank 10M of the vaporizer 10 may be additionally provided with a stirring device or a swinging device for promoting movement or flow of the ultrapure water stored in the vaporization chamber.

The stirring device may be constructed, for example, by a mechanical mechanism that move the bottom heater 14B up and down, side to side or vibrate. Of course, it may be a device which is separated from the bottom heater 14B and rotates a vane member submerged in the water. In addition, it is also possible to move the ultrapure water in the vaporization chamber 12 by swinging the main tank 10M itself using the swinging device. By actively moving the ultrapure water in this manner, it is possible to further improve the heating efficiency and the heating speed, and shorten the heating time up to the desired temperature.

The embodiment of supplying ultrapure water gas with controlled flow rate by using the pressure type flow rate control device connected to the downstream side of the vaporizer is described above, the flow rate control may be performed by using a flow rate control devices with another aspects.

### INDUSTRIAL APPLICABILITY

The vaporizer and vaporization supply device according to the embodiments of the present invention is suitably utilized for vaporing ultrapure water and then supplying it to the ashing device of the semiconductor manufacturing facility.

### REFERENCE SIGNS LIST

2 Ultrapure water source
4 Shut-off valve
6 Process chamber
8 Vacuum pump
10 Vaporizer
10M Main tank
10P Pre-tank
12 Vaporization chamber
14B Bottom heater
14S Side heater
141 Winding portion
142 Upright portion
143 Heater terminal
16 Relief valve
18 Level sensor
19 Supply pressure sensor
20 Pressure type flow rate control device
22 Control valve
24 Restriction part
26 Upstream pressure sensor
100 Vaporization supply device

1. A vaporizer comprising:
a vaporization chamber for storing a liquid;
a bottom heater provided in the vaporization chamber, the bottom heater including a winding portion acting as a heat source arranged so as to contact with the liquid stored in the vaporization chamber, and an upright portion erected from the winding portion and having an end portion with a heater terminal; and
a relief valve connected to the vaporization chamber.

2. The vaporizer according to claim 1, further comprising a side heater for heating a side surface of the vaporization chamber from an outside of the vaporization chamber.

3. The vaporizer according to claim 1, further comprising a pre-tank having a heater for preheating a liquid to be delivered to the vaporization chamber.

4. The vaporizer according to claim 1, further comprising a float sensor for measuring a liquid level of the liquid, wherein the winding portion of the bottom heater is provided at a position lower than a liquid level lower limit position of the float sensor.

5. The vaporizer according to claim 1, further comprising a stirring device or a swinging device for promoting movement of the liquid stored in the vaporization chamber.

6. The vaporizer according to claim 1, wherein the liquid is ultrapure water, and the vaporizer is used to supply vaporized ultrapure water to an ashing device.

7. A vaporization supply device comprising:
the vaporizer according to claim 1; and
a pressure type flow rate control device provided downstream of the vaporizer, the pressure type flow rate control device including: a restriction part; a control valve provided upstream of the restriction part; and an upstream pressure sensor for measuring a pressure between the restriction part and the control valve,
wherein the pressure type flow rate control device is configured to control a flow rate of a gas flowing downstream of the restriction part by adjusting an opening degree of the control valve based on an output of the upstream pressure sensor.
